(19) United States
(12) Patent Application Publication
(10) Pub. No.: US 2017/0208396 A1
(43) Pub. Date: Jul. 20, 2017

(54) Acoustic Energy Harvesting Device

(71) Applicants: Kristina Dronenburg, Lexington Park, MD (US); Zachary Keiter, Hollywood, MD (US); Jazmin Myres, Lexington Park, MD (US); Cesar Rios, Great Mills, MD (US)

(72) Inventors: Kristina Dronenburg, Lexington Park, MD (US); Zachary Keiter, Hollywood, MD (US); Jazmin Myres, Lexington Park, MD (US); Cesar Rios, Great Mills, MD (US)

(73) Assignee: United States of America as represented by the Secretary of the Navy, Patuxent River, MD (US)

(21) Appl. No.: 14/995,361

(22) Filed: Jan. 14, 2016

(51) Int. Cl. H04R 17/10; H01L 41/113

(52) U.S. Cl. CPC H04R 17/10; H01L 41/1138

(57) ABSTRACT

An acoustic energy harvesting device that includes a plurality of transducers for the collection of acoustic energy from an acoustic source and for converting the acoustic energy into electrical energy, a plurality of series clusters forming a transducer array, a transducer array panel for holding the transducers, and a back plate. Each transducer has a rectifying circuit for making voltage and current rectified. Each series cluster has a set of transducers connected in series, and the series clusters are connected in parallel such that the voltage and the current derived from the rectified transducers is increased and can be fed into a storage device. The back plate is disposed behind the transducer array such that the back plate creates an amplifying effect by increasing pressure impingement on the transducers such that output of the electrical energy is increased.

### STATEMENT OF GOVERNMENT INTEREST

The invention described herein may be manufactured and used by or for the Government of the United States of America for governmental purposes without payment of any royalties thereon or therefor.

### BACKGROUND

Universities and research labs have performed much research on acoustic energy harvesting. Most methods utilize piezoelectric transducers as the energy harvesting transducer. Additionally, most research focuses on a single relatively high frequency, and most devices that harvest acoustic energy do not have the ability to harvest acoustic energy with low frequencies below 1 kHz.

### SUMMARY

The present invention is directed to an acoustic energy harvesting device with the needs enumerated above and below.

The present invention is directed to an acoustic energy harvesting device that includes a plurality of transducers, a plurality of series clusters forming a transducer array, a transducer array panel for holding the transducers, and a back plate. The transducers are for the collection of acoustic energy from an acoustic source and for converting the acoustic energy into electrical energy. The electrical energy has a voltage and a current. Each transducer has a rectifying circuit for making the voltage and the current rectified. Each series cluster has a set of transducers connected in series, and the series clusters are connected in parallel such that the voltage and the current derived from the rectified transducers is increased and can be fed into a storage device. The back plate is disposed behind the transducer array such that the back plate creates an amplifying effect by increasing pressure impingement on the transducers such that output of the electrical energy is increased.

It is a feature of the present invention to provide an acoustic energy harvesting device that can collect acoustic energy and convert that energy to electrical energy.

It is a feature of the present invention to provide an acoustic energy harvesting device that does not utilize piezoelectric transducers as the primary transducer element.

It is a feature of the present invention to provide an acoustic energy harvesting device that is able to harvest low frequencies below 1 kHz.

It is a feature of the present invention to provide an acoustic energy harvesting device that produces much higher wattages from any other available methods, and has enough energy to provide charge to an aircraft battery.

It is a feature of the present invention to provide an acoustic energy harvesting device that is a passive energy collection device that requires no power input to operate.

### DRAWINGS

These and other features, aspects and advantages of the present invention will become better understood with reference to the following description and appended claims, and accompanying drawings wherein:

FIG. 1 is perspective view of an embodiment of the acoustic energy harvesting device;

FIG. 2 is a circuit diagram of an embodiment of a transducer;

FIG. 3 is a circuit diagram of an embodiment of a series cluster;

FIG. 4 is a circuit diagram of another embodiment of a series cluster;

FIG. 5 is a circuit design of a plurality of series clusters in parallel; and

FIG. 6 is a location invention diagram which shows the measurement zone for the location of the acoustic energy harvesting device in order to optimally harvest acoustic energy from a tactical military aircraft.

### DESCRIPTION

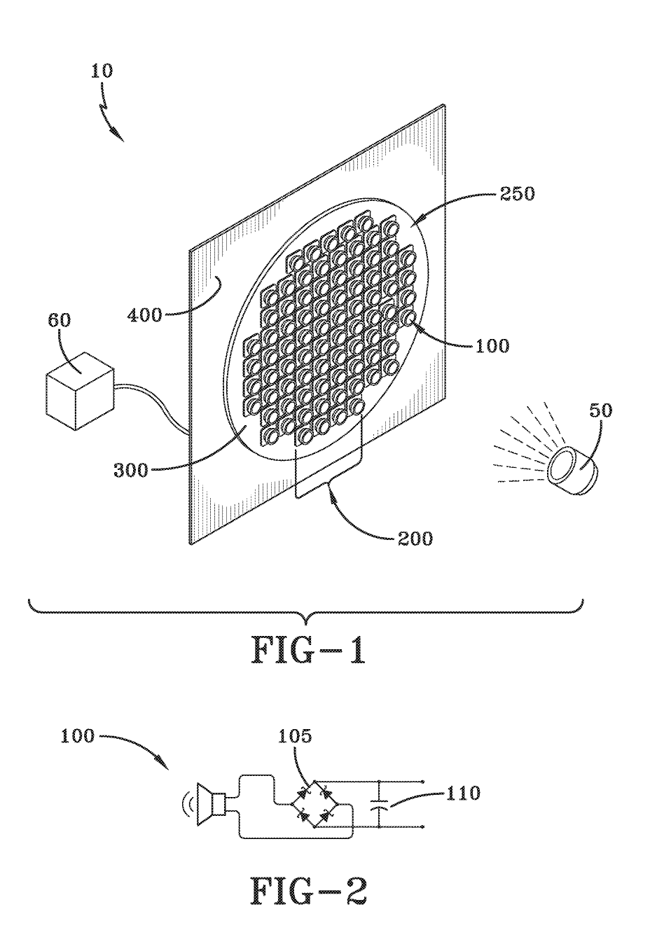

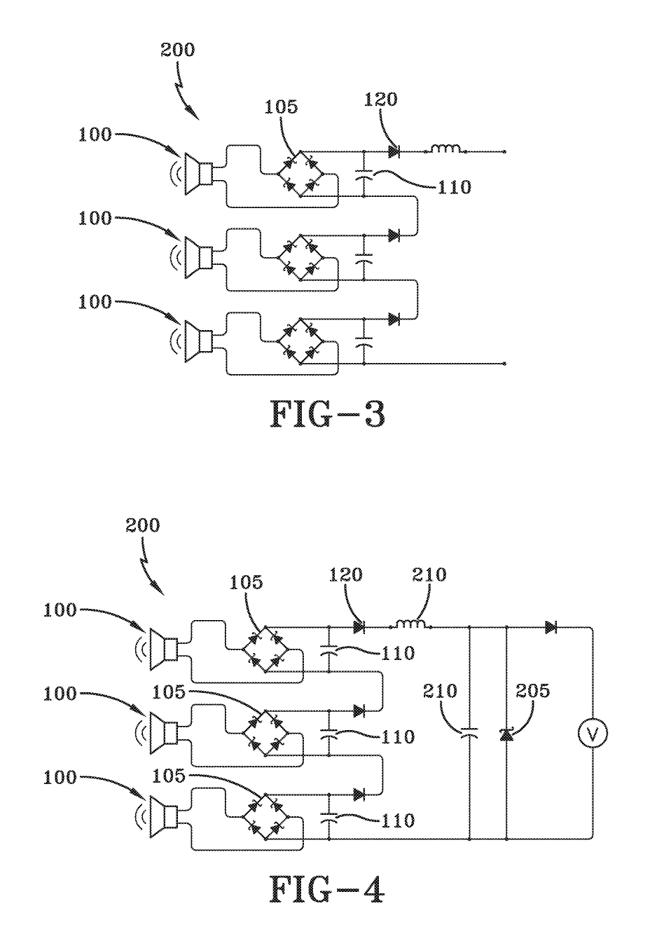

The preferred embodiments of the present invention are illustrated by way of example below and in FIGS. 1-6. As shown in FIG. 1, the acoustic energy harvesting device 10 includes a plurality of transducers 100, a plurality of series clusters 200 forming a transducer array 250, a transducer array panel 300 for holding the transducers 100, and a back plate 400. The transducers 100 are for the collection of acoustic energy from an acoustic source 50 and for converting the acoustic energy into electrical energy. The electrical energy has a voltage and a current, and the acoustic energy has a frequency. As shown in FIG. 2, each transducer 100 has a rectifying circuit 105 for making the voltage and the current rectified. As shown in FIG. 3, each series cluster 200 has a set of transducers 100 connected in series, and the series clusters 200 are connected in parallel such that the voltage and the current derived from the rectified transducers is increased and can be fed into a storage device 60 such as a battery. The back plate 400 is disposed behind the transducer array 250 such that the back plate 400 creates an amplifying effect of the acoustic energy by increasing pressure impingement on the transducers 100 such that output of the electrical energy is increased.

In the description of the present invention, the invention will be discussed in a military aircraft environment as the acoustic source is a military jet engine; however, this invention can be utilized for any type of application that requires use of an acoustic energy harvesting device.

The preferred transducers 100 are transducers that have a resonant frequency matching the acoustic energy peak frequency.

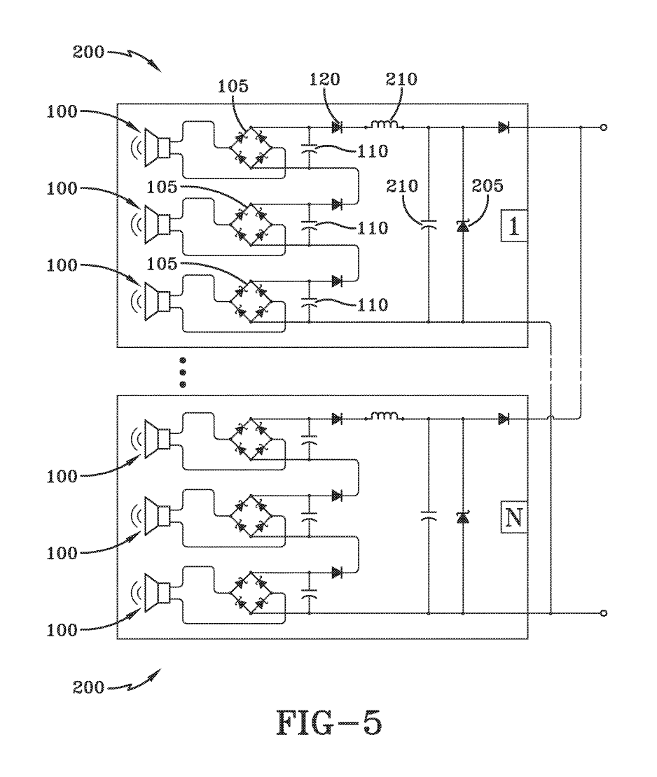

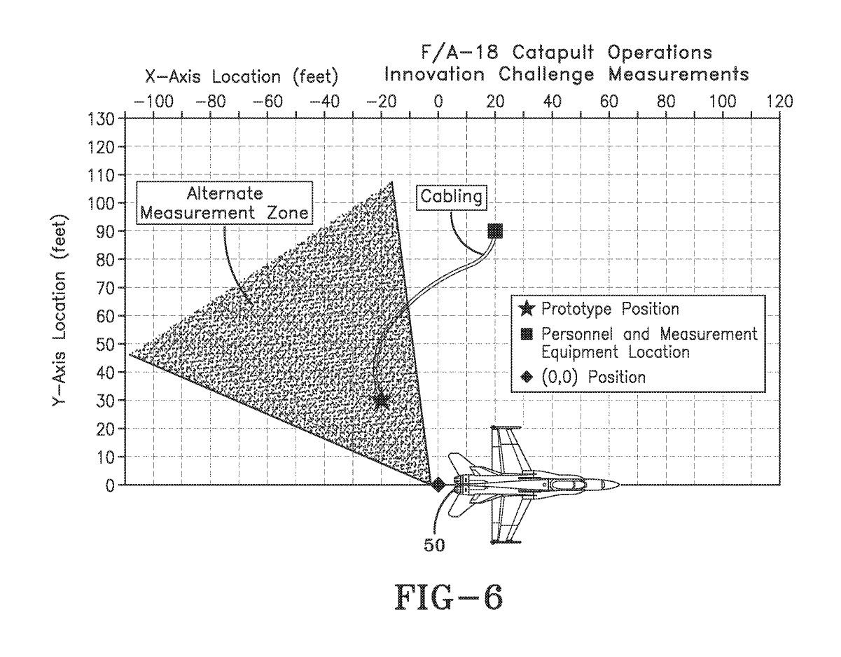

A series cluster 200 includes a plurality of transducers 100, which may be speakers. Acoustic energy enters a transducer 100 which converts the acoustic energy to electrical energy and the voltage and current is rectified by a rectifying circuit 105, and is then converted from alternating current to direct current. As shown in FIG. 2, the preferred rectifying circuit 105 is a full bridge Schottky rectifier followed by a capacitor 110. As shown in FIG. 3, in the preferred embodiment, a series cluster 200 includes three rectified transducers 100 connected in series. Additionally, a diode 120 may be placed at the output of the signal exiting the series cluster 200, in order to avoid current retro feeding. As shown in FIG. 4, the series cluster 200 may additionally include zener diodes 205 and LC filters 210 to obtain a desired voltage. As shown in FIG. 5, the plurality of series clusters 200 are connected in parallel.

In operation, the acoustic energy harvesting device 10 is placed in a location which allows easy noise collection. For instance, in aircraft, particularly tactical military aircraft, the device 10 is optimally placed approximately 30 feet aft and 30 feet sideline of the rear of the aircraft as shown in FIG. 6.

When introducing elements of the present invention or the preferred embodiment(s) thereof, the articles “a,” “an,” “the,” and “said” are intended to mean there are one or more of the elements. The terms “comprising,” “including,” and “having” are intended to be inclusive and mean that there may be additional elements other than the listed elements.

Although the present invention has been described in considerable detail with reference to certain preferred embodiments thereof, other embodiments are possible. Therefore, the spirit and scope of the appended claims should not be limited to the description of the preferred embodiment(s) contained herein.

What is claimed is:

1. An acoustic energy harvesting device comprising:
a plurality of transducers, the transducers for the collection of acoustic energy from an acoustic source and for converting the acoustic energy into electrical energy, the electrical energy having a voltage and a current, each transducer having a rectifying circuit for making the voltage and the current rectified;
a plurality of series clusters forming a transducer array, each series cluster comprising of a set of transducers connected in series, the series clusters are connected in parallel such that the voltage and the current derived from the rectified transducers is increased and can be fed into a storage device;
a transducer array panel for holding the transducers;
a back plate disposed behind the transducer array such that the back plate creates an amplifying effect by increasing pressure impingement on the transducers such that output of the electrical energy is increased.

2. The acoustic energy harvesting device of claim 1 whereby the rectifying circuit is a full bridge Schottky rectifier.

3. The acoustic energy harvesting device of claim 2 wherein the acoustic energy has a peak frequency and the transducers that have a resonant frequency matching the peak frequency of the acoustic energy.
